(19) United States
(12) Patent Application Publication
(10) Pub. No.: US 2012/0119866 A1
(43) Pub. Date: May 17, 2012

(54) NON-MAGNETIC MATERIAL COMPOSITION FOR CERAMIC ELECTRONIC COMPONENT, CERAMIC ELECTRONIC COMPONENT MANUFACTURED BY USING THE SAME, AND METHOD OF MANUFACTURING THE CERAMIC ELECTRONIC COMPONENT

(75) Inventors: Ic Seob KIM, Yongin (KR); Sung Lyoung Kim, Bucheon (KR); Soo Hwan Son, Seoul (KR); Jin Woo Hahn, Yongin (KR); Sung Yong An, Anyang (KR)

(73) Assignee: SAMSUNG ELECTRO-MECHANICS CO., LTD.

(21) Appl. No.: 13/048,107

(22) Filed: Mar. 15, 2011

(30) Foreign Application Priority Data
Nov. 16, 2010 (KR) 10-2010-0114136

(51) Int. Cl. H01F 5/00; C04B 35/462; H05K 13/00; C01G 23/04

(52) U.S. Cl. 336/200; 423/598; 501/134; 29/825

(57) ABSTRACT

There is provided a non-magnetic material composition for a ceramic electronic component, a ceramic electronic component manufactured by using the same, and a method of manufacturing the ceramic electronic component. The non-magnetic material composition for the ceramic electronic component includes a compound represented by Chemical Formula Zn₂TiO₄. According to an exemplary embodiment of the present invention, the ceramic electronic component has improved DC bias characteristics by applying the non-magnetic material composition having no magnetic characteristics thereto.

### CROSS-REFERENCE TO RELATED APPLICATIONS

This application claims the priority of Korean Patent Application No. 10-2010-0114136 filed on Nov. 16, 2010, in the Korean Intellectual Property Office, the disclosure of which is incorporated herein by reference.

### BACKGROUND OF THE INVENTION

1. Field of the Invention

The present invention relates to a non-magnetic material composition for a ceramic electronic component capable of improving bias characteristics, a ceramic electronic component manufactured by using the same, and a method of manufacturing the ceramic electronic component.

2. Description of the Related Art

An inductor, an important passive device, together with a resistor and a capacitor, is used in the configuration of an electronic circuit, to remove noise or to configure an LC resonance circuit therein.

The inductor may be manufactured by winding a coil on a ferrite core. Further, the inductor may be manufactured by printing internal electrodes on a magnetic green sheet or a dielectric green sheet and stacking the same.

Inductors may be classified according to the structure thereof, such as a multilayer type, a winding type, a thin film type, and the like. Among these, a multilayer inductor has been widely propagated.

The multilayer inductor includes a plurality of magnetic sheets made of ferrite or a dielectric material having a low dielectric constant.

Coil-shaped conductive patterns are formed on the magnetic sheets. The coil-shaped conductive patterns formed on the individual magnetic sheets form internal electrode layers.

Further, the internal electrode layers are electrically connected in series through via electrodes formed on ferrite sheets.

The multilayer inductor may be manufactured as a separate component having a chip shape and may be formed in a state in which it is embedded in a substrate, together with other modules.

A general multilayer inductor has a structure in which a plurality of magnetic layers having the conductive patterns are laminated. The conductive patterns are sequentially connected through via electrodes formed on the individual magnetic layers, and the magnetic layers form a spiral coil while being overlapped according to a lamination direction.

Further, the multilayer inductor has a structure in which both ends of the coil are drawn out from an outer surface of a laminate and connected with external terminals.

As described above, since the multilayer inductor has a structure in which the coil is surrounded by the magnetic material such as ferrite, the magnetic material around the coil is magnetized when high current is applied to the coil.

There is a problem, however, in that the inductance characteristics of the inductor may be deteriorated due to the change in inductance (L) value of the inductor by the magnetization around the coil.

### SUMMARY OF THE INVENTION

An aspect of the present invention provides a non-magnetic material composition for a ceramic electronic component capable of improving bias characteristics of the ceramic electronic component, a ceramic electronic component manufactured by using the same, and a method of manufacturing the ceramic electronic component.

According to an aspect of the present invention, there is provided a non-magnetic material composition for a ceramic electronic component including a compound represented by Chemical Formula Zn₂TiO₄.

The compound may be a powder and may be prepared by mixing and calcining zinc oxide (ZnO) and titanium dioxide (TiO₂).

The compound may be prepared by reacting 0.65 mol to 0.67 mol of zinc oxide and 0.33 mol to 0.35 mol of titanium dioxide.

The non-magnetic material composition may further include a sintering agent.

The sintering agent may be at least one of B₂O₃ and CuO and may be 1 to 5 parts by weight per 100 parts by weight of the compound.

According to another aspect of the present invention, there is provided a ceramic electronic component including: a ceramic main body in which a plurality of magnetic layers are stacked; internal electrode layers formed in the ceramic main body; a non-magnetic layer inserted between the magnetic layers and including a compound represented by Chemical Formula Zn₂TiO₄; and external electrodes formed on outside ends of the ceramic main body and electrically connected with the internal electrode layers.

According to another aspect of the present invention, there is provided a method of manufacturing a ceramic electronic component, the method including: preparing a plurality of magnetic layers; preparing a non-magnetic layer including a compound represented by Chemical Formula Zn₂TiO₄; forming internal electrode layers in the plurality of magnetic layers; forming a laminate by inserting the non-magnetic layer between the plurality of magnetic layers; forming a ceramic main body by firing the laminate; and forming external electrodes on outside ends of the ceramic main body to be electrically connected with the internal electrode layers.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is an external perspective view showing an example of a ceramic electronic component according to an exemplary embodiment of the present invention;

FIG. 2 is a cross-sectional view taken along line A-A of the ceramic electronic component shown in FIG. 1;

FIGS. 3A through 3D are views showing a method of manufacturing a ceramic electronic component according to an exemplary embodiment of the present invention;

FIG. 4 is an electron probe micro analyzer (EPMA) image showing the diffusion of components of a non-magnetic layer of a multilayer ceramic inductor according to an exemplary embodiment of the present invention;

FIG. 5 is a graph showing DC bias characteristics according to temperature in inventive and comparative examples according to an exemplary embodiment of the present invention; and

FIG. 6 is a graph showing inductance change rates in inventive and comparative examples according to an exemplary embodiment of the present invention.

### DETAILED DESCRIPTION OF THE PREFERRED EMBODIMENT

Hereinafter, exemplary embodiments will be described in detail with reference to the accompanying drawings so that they can be easily practiced by those skilled in the art to which the present invention pertains. However, in describing the exemplary embodiments of the present invention, detailed descriptions of well-known functions or constructions are omitted so as not to obscure the description of the present invention with unnecessary detail.

A non-magnetic material composition for a ceramic electronic component according to an exemplary embodiment of the present invention includes a compound represented by Chemical Formula ZnTiO₄.

In the manufacturing of a ceramic electronic component, a non-magnetic layer is inserted between magnetic layers in order to obtain a magnetic field shielding effect. A non-magnetic layer according to the related art is made of a ZnFe₂O₄-based material, and is manufactured in the form of ZnCuFe₂O₄ by adding CuO thereto for contraction behavior matching and sinter bonding with the magnetic layers during the simultaneous sinter bonding thereof.

However, CuFe₂O₄ having magnetic characteristics is generated corresponding to an amount of added Cu due to the CuO being added in order to secure the sinter bonding, such that the ceramic electronic component has slight magnetic behavior.

In addition, the non-magnetic layer is partially magnetized since (NiZnCu)ₓFe₂₋ₓO₄ magnetic material is formed on the interface between the magnetic layer and the non-magnetic layer due to the diffusion of components therebetween during sintering.

Magnetic field shielding, generated when current is applied to the ceramic electronic component due to the above-mentioned magnetic behavior, is deteriorated and thus, DC bias characteristics are deteriorated.

Therefore, according to an exemplary embodiment of the present invention, a non-magnetic material composition including a compound represented by Chemical Formula Zn₂TiO₄ is provided in order to solve the problems.

The compound represented by Chemical Formula Zn₂TiO₄ is a complete non-magnetic material composition that does not have magnetic characteristics, such that the magnetic flux shielding characteristics thereof are excellent, whereby the DC bias characteristics may be improved.

The non-magnetic material composition according to the exemplary embodiment of the present invention has complete non-magnetic characteristics, and a detailed description thereof will be described below.

In an electron arrangement of atoms or ions, it is determined whether or not unpaired electrons, which are one of factors of revealing the magnetic characteristics of a material, are present by measuring a magnetic moment of the material.

The magnitude of the magnetic moment is determined according to the number of unpaired electrons (d orbital electrons of atom). In the case that the number of unpaired electrons is n, the approximate magnitude of the magnetic moment is represented as follows:

μ=\sqrt{n(n+2)}

This is referred to as a spin only formula, where the unit of measurement for the magnetic moment μ is Bohr magneton (BM).

The electron arrangement and the magnetic moment of several ions, used as a material for the existing non-magnetic layer, are as follows:

$$Electron Arrangement of {Fe}^{3 +} \text{:} \\ [ Ar ] 3 {d}^{5} 4 {S}^{0} {\underline{\begin{matrix}↑ & \end{matrix}} \underline{\begin{matrix}↑ & \end{matrix}} \underline{\begin{matrix}↑ & \end{matrix}} \underline{\begin{matrix}↑ & \end{matrix}} \underline{\begin{matrix}↑ & \end{matrix}}}_{3 d} {\begin{matrix} & \end{matrix}}_{{\_}_{4 s}}$$

$$μ ( {Fe}^{3 +} ) = \sqrt{5 ( 5 + 2 )} = 5.91 BM$$

$$Electron Arrangement of {Zn}^{2 +} \text{:} \\ [ Ar ] 3 {d}^{10} 4 {s}^{0} {\underline{\begin{matrix}↑ & ↓\end{matrix}} \underline{\begin{matrix}↑ & ↓\end{matrix}} \underline{\begin{matrix}↑ & ↓\end{matrix}} \underline{\begin{matrix}↑ & ↓\end{matrix}}}_{3 d} \underline{\begin{matrix}↑ & ↓\end{matrix}} { \begin{matrix} & \end{matrix}}_{{\_}_{4 s}}$$

$$μ ( {Zn}^{2 +} ) = \sqrt{0 ( 0 + 2 )} = 0 BM$$

$$Electron Arrangement of {Cu}^{2 +} \text{:} \\ [ Ar ] 3 {d}^{9} 4 {s}^{0} {\underline{\begin{matrix}↑ & ↓\end{matrix}} \underline{\begin{matrix}↑ & ↓\end{matrix}} \underline{\begin{matrix}↑ & ↓\end{matrix}} \underline{\begin{matrix}↑ & ↓\end{matrix}}}_{3 d} \underline{\begin{matrix}↑ & \end{matrix}} {\begin{matrix} & \end{matrix}}_{{\_}_{4 s}}$$

$$μ ( {Cu}^{2 +} ) = \sqrt{1 ( 1 + 2 )} = 1.73 BM$$

The existing ZnCuFe₂O₄-based non-magnetic layer has magnetic characteristics of about 1.5 emu/g to 2.5 emu/g in terms of saturation magnetization (Ms).

On the other hand, the electron arrangement and the magnetic moment of a metal ion state of two elements in the compound represented by Chemical Formula Zn₂TiO₄ according to the exemplary embodiment of the present invention are as follows:

$$Electron Arrangement of {Zn}^{2 +} \text{:} \\ [ Ar ] 3 {d}^{10} 4 {S}^{0} {\underline{\begin{matrix}↑ & ↓\end{matrix}} \underline{\begin{matrix}↑ & ↓\end{matrix}} \underline{\begin{matrix}↑ & ↓\end{matrix}} \underline{\begin{matrix}↑ & ↓\end{matrix}}}_{3 d} \underline{\begin{matrix}↑ & ↓\end{matrix}} {\begin{matrix} & \end{matrix}}_{{\_}_{4 s}}$$

$$μ ( {Zn}^{2 +} ) = \sqrt{0 ( 0 + 2 )} = 0 BM$$

$$Electron Arrangement of {Ti}^{4 +} \text{:} \\ [ Ar ] 3 {d}^{0} 4 {s}^{0} {\underline{\begin{matrix} & \end{matrix}} \underline{\begin{matrix} & \end{matrix}} \underline{\begin{matrix} & \end{matrix}} \underline{\begin{matrix} & \end{matrix}}}_{3 d} \underline{\begin{matrix} & \end{matrix}} { \begin{matrix} & \end{matrix}}_{{\_}_{4 s}}$$

$$μ ( {Ti}^{4 +} ) = \sqrt{0 ( 0 + 2 )} = 0 BM$$

ZnO and TiO₂, which are oxides of two metallic elements, are synthesized as a compound having a Zn₂TiO₄ structure by mixing two components at a relatively low temperature. In this case, the magnetic moment is 0, which shows the complete non-magnetic characteristics, such that a magnetic field shielding is achieved.

Further, in the compound represented by Chemical Formula Zn₂TiO₄ according to the exemplary embodiment of the present invention, zinc (Zn), a metallic element, can control the diffusion of components of titanium oxide (TiO₄). The compound includes the same zinc (Zn) as that of the material for magnetic layers, such that it is advantageous in securing sinter bonding according to a homogenous material.

The compound may be a powder and may be prepared by mixing and calcining zinc oxide (ZnO) and titanium dioxide (TiO₂).

In addition, the compound may be prepared by reacting 0.65 mol to 0.67 mol of zinc oxide and 0.33 mol to 0.35 mol of titanium dioxide.

Meanwhile, the non-magnetic material composition for the ceramic electronic component may further include a sintering agent for contraction behavior matching when it is bonded to the magnetic layers and is subjected to simultaneous sintering therewith.

The sintering agent may be at least one of B₂O₃ and CuO and may have the content of 1 to 5 parts by weight per 100 parts by weight of the compound.

Even in the case that the sintering agent is added to the non-magnetic material composition including the compound represented by Chemical Formula Zn TiO₄ according to the exemplary embodiment of the present invention, the composition does not have the magnetic characteristics, thereby improving the DC bias characteristics.

Further, the interfacial bonding with the magnetic layers is controlled by the addition of the sintering agent, such that the delamination of the magnetic layers and the non-magnetic layer affecting the yield of the ceramic electronic component can be effectively prevented.

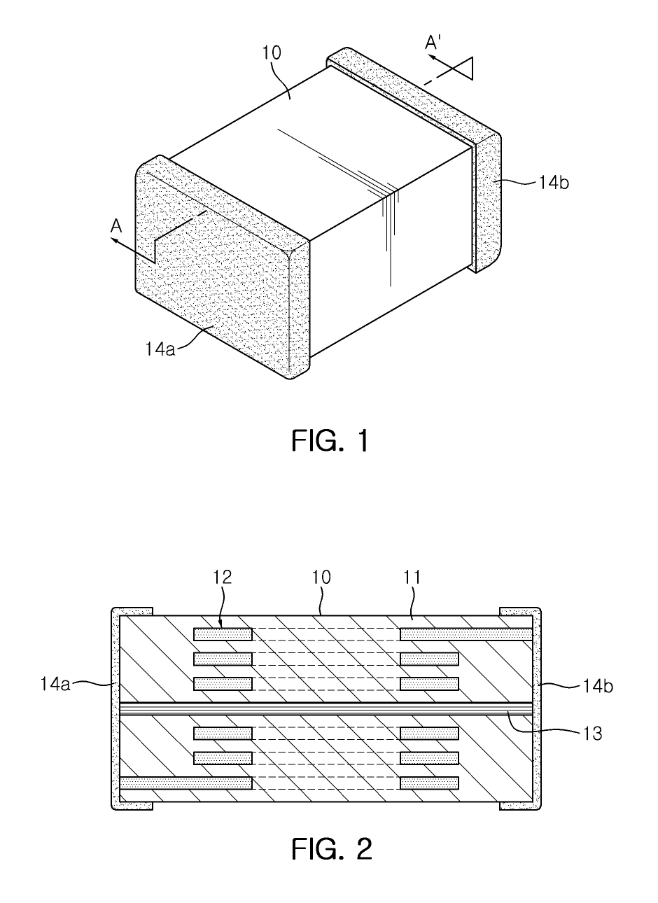

FIG. 1 is an external perspective view showing an example of a ceramic electronic component according to an exemplary embodiment of the present invention.

FIG. 2 is a cross-sectional view, taken along line A-A, of the ceramic electronic component shown in FIG. 1 according to the exemplary embodiment of the present invention.

As an example of the ceramic electronic component, a multilayer ceramic inductor will be described below.

Referring to FIGS. 1 and 2, a multilayer ceramic inductor according to an exemplary embodiment of the present invention includes: a ceramic main body 10 in which a plurality of magnetic layers 11 are stacked; internal electrode layers 12 formed in the ceramic main body 10; a non-magnetic layer 13 inserted between the magnetic layers 11 and including a compound represented by Chemical Formula Zn₂TiO₄; and external electrodes 14a and 14b formed on outside ends of the ceramic main body 10 and electrically connected to the internal electrode layers 12.

In the exemplary embodiment of the present invention, the ceramic main body has a structure in which the non-magnetic layer 13 including the compound represented by Chemical Formula Zn₂TiO₄ is inserted between the magnetic layers 11. In this case, the compound shows complete non-magnetic characteristics as described above, and thus, a ceramic electronic component having improved DC bias characteristics can be provided.

In addition, the non-magnetic layer 13 may further include a sintering agent, such that interfacial bonding with the magnetic layers 11 may be controlled, thereby having a superior effect in preventing the delamination of the magnetic layers 11 and the non-magnetic layer 13 affecting the yield of the ceramic electronic component.

In addition, when electricity is applied to the ceramic electronic component, a magnetic field is formed in the internal electrode layers 12, but is shielded more excellently by the non-magnetic layer 13, thereby allowing for improved DC bias characteristics.

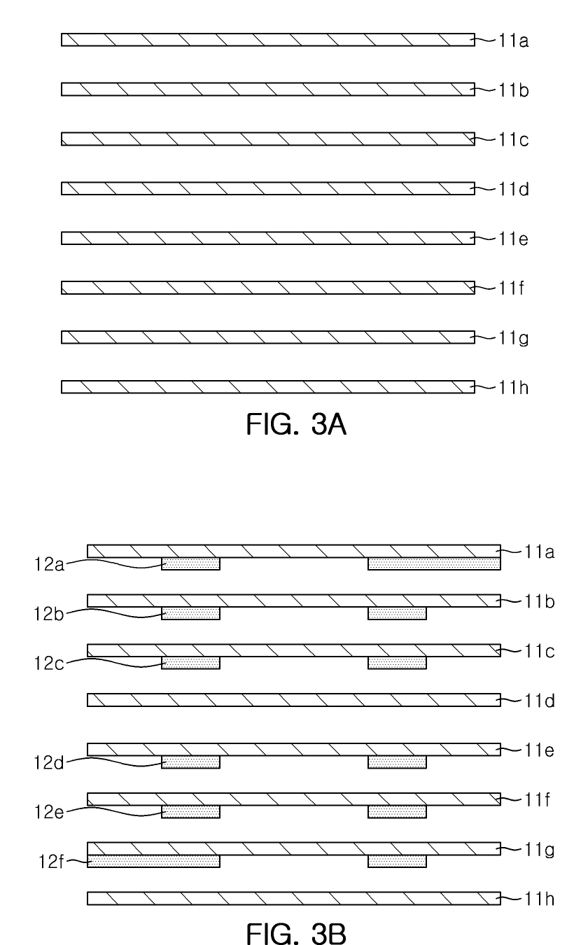

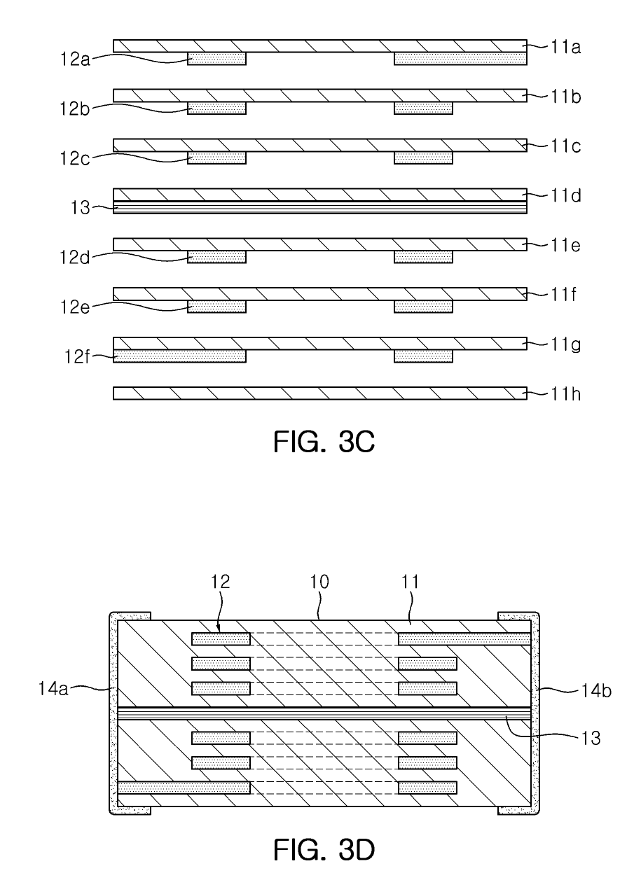

FIGS. 3A through 3D are views showing a method of manufacturing a ceramic electronic component according to an exemplary embodiment of the present invention.

Referring to FIGS. 3A through 3D, a method of manufacturing a ceramic electronic component according to an exemplary embodiment of the present invention includes: preparing a plurality of magnetic layers 11a, 11b, 11c, 11d, 11e, 11f, 11g, and 11h; preparing the non-magnetic layer 13 including the compound represented by Chemical Formula Zn TiO₄; forming internal electrode layers 12a, 12b, 12c, 12d, 12e, and 12f on the plurality of magnetic layers 11a, 11b, 11c, 11d, 11e, 11f, 11g, and 11h; forming a laminate by inserting the non-magnetic layer 13 between the plurality of magnetic layers 11a, 11b, 11c, 11d, 11e, 11f, 11g, and 11h; forming the ceramic main body 10 by firing the laminate; and forming external electrodes 14a and 14b on the outside ends of the ceramic main body 10 to be electrically connected with the internal electrode layers 12.

First, as shown in FIG. 3A, the plurality of magnetic layers 11a, 11b, 11c, 11d, 11e, 11f, 11g, and 11h may be prepared.

The plurality of magnetic layers are taken as an example in this embodiment; however the number of layers is not limited thereto. The number of layers may be determined according to the purpose of the ceramic electronic component.

The magnetic layers may be prepared by a general method and the material thereof is not specifically limited. For example, NiZnCuFe₂O₄ may be used therefor.

In addition, the non-magnetic layer including the compound represented by Chemical Formula Zn₂TiO₄ is prepared and the non-magnetic layer may be manufactured by using the above-mentioned non-magnetic material composition.

Next, as shown in FIG. 3B, the internal electrode layers 12a, 12b, 12c, 12d, 12e, and 12f may be formed in the plurality of magnetic layers 11a, 11b, 11c, 11d, 11e, 11f, 11g, and 11h.

The internal electrode layers 12a, 12b, 12c, 12d, 12e, and 12f may be formed by a general method, and the material thereof is not specifically limited thereto. For example, the internal electrode layers may be made of at least one of Ag, Pt, Pd, Au, Cu, and Ni or an alloy thereof.

In addition, according to an exemplary embodiment of the present invention, the internal electrode layers 12a, 12b, 12c, 12d, 12e, and 12f are individually connected to via electrodes (not shown), thereby forming a coil structure.

Next, as shown in FIG. 3C, the laminate is formed by inserting the non-magnetic layer 13 between the plurality of magnetic layers 11a, 11b, 11c, 11d, 11e, 11f, 11g, and 11h.

The non-magnetic layer 13 is positioned between the plurality of magnetic layers 11a, 11b, 11c, 11d, 11e, 11f, 11g, and 11h, but the position thereof is not specifically limited.

The non-magnetic layer 13 is prepared by using the non-magnetic material composition according to the exemplary embodiment of the present invention, thereby showing the complete non-magnetic characteristics.

Next, the ceramic main body 10 is formed by firing the laminate. In the present embodiment, since the non-magnetic layer 13 may include the sintering agent, the interfacial bonding with the magnetic layers 11 is satisfactory, whereby the delamination of the magnetic layers and the non-magnetic layer, affecting the yield of the ceramic electronic component, is effectively prevented.

Further, the compound represented by Chemical Formula Zn₂TiO₄ according to the exemplary embodiment of the present invention improves a change in bias temperature characteristics due to an increase in diffusion layers, since zinc (Zn), which is a metallic element, controls the diffusion of components of titanium oxide (TiO₄).

In addition, the non-magnetic layer 13 includes zinc (Zn), which is the same metallic element as that of the material for the magnetic layers 11, such that it has satisfactory sinter bonding.

As shown in FIG. 3D, the external electrodes 14a and 14b are formed on the outside ends of the ceramic main body 10 to be electrically connected with the internal electrode layers 12, and thus the ceramic electronic component is manufactured.

Hereinafter, the present invention will be described below in more detail with reference to inventive and comparative examples, but the scope of the invention is not limited thereto.

### Inventive Examples

A non-magnetic layer was prepared to include 5 parts by weight of CuO and 5 parts by weight of B₂O₃ per 100 parts by weight of Zn₂TiO₄ compound, (Inventive Example 1), and a non-magnetic layer was prepared to include 3 parts by weight of CuO and 3 parts by weight of B₂O₃ per 100 parts by weight of Zn₂TiO₄ compound (Inventive Example 2).

A plurality of magnetic layers were prepared by using NiZnCuFe₂O₄ as a material, and a multilayer ceramic inductor was prepared by stacking the non-magnetic layer between the magnetic layers.

### Comparative Examples

A non-magnetic layer was prepared to include 100 parts by weight of ZnCuFe₂O₄.

A plurality of magnetic layers were prepared by using NiZnCuFe₂O₄ as a material, and a multilayer ceramic inductor was prepared by stacking the non-magnetic layer between the magnetic layers.

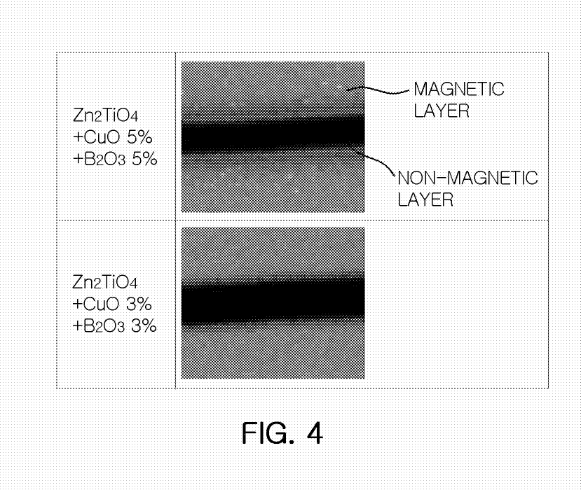

FIG. 4 is an image of an electron probe micro analyzer (EPMA) showing the diffusion of components of a non-magnetic layer in a multilayer ceramic inductor according to an exemplary embodiment of the present invention.

As shown in FIG. 4, since the non-magnetic layer was prepared to include the compound represented by Chemical Formula Zn TiO₄, it can be seen that the non-magnetic layer is bonded to the magnetic layers without the diffusion of components of titanium oxide, in spite of the application of an additive, by allowing a metallic element zinc (Zn) to control the diffusion of the components.

Therefore, according to the exemplary embodiment of the present invention, the non-magnetic layer is sinter-bonded to the magnetic layers, and the bonding may be made without the diffusion.

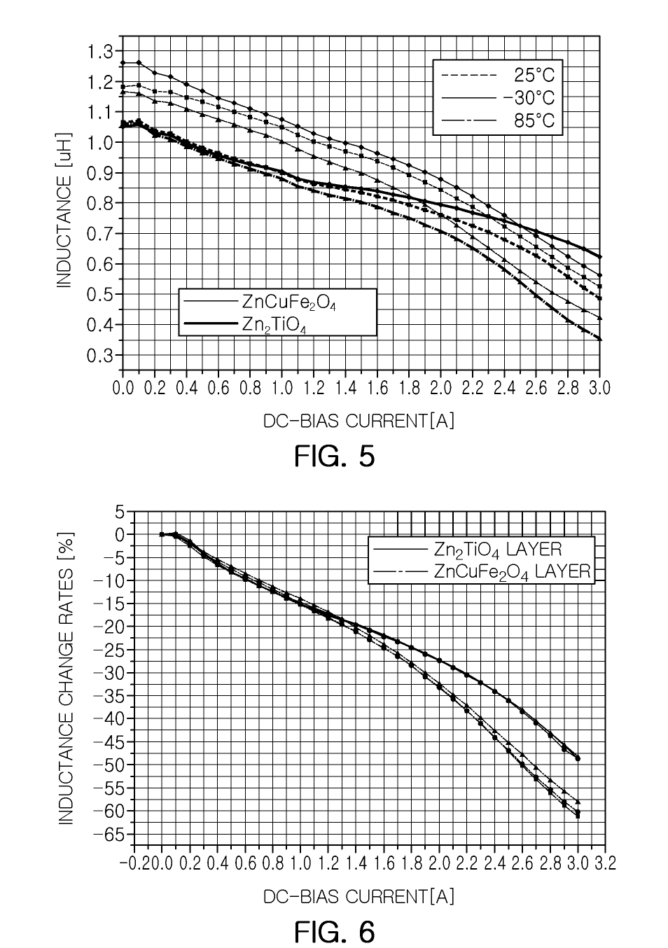

FIG. 5 is a graph showing DC bias characteristics according to temperature in inventive and comparative examples according to an exemplary embodiment of the present invention.

In FIG. 5, a graph showing inductance characteristics according to temperature in Inventive Example 1 of the present invention is represented by a thick line.

As shown in FIG. 5, it can be seen that the inductance characteristics according to temperature in Inventive Example of the present invention were stable as compared to Comparative Example.

FIG. 6 is a graph showing inductance change rates in inventive and comparative examples according to an exemplary embodiment of the present invention.

FIG. 6 shows the results of a comparison of the inductance change rates according to the application of the DC bias. It can be seen that Inventive Example 1 of the present invention shows a smaller inductance change rate at a high current than that of Comparative Example and thus, the DC bias characteristics thereof was improved.

As set forth above, according to exemplary embodiments of the invention, a ceramic electronic component has improved DC bias characteristics by applying a non-magnetic material composition having no magnetic characteristics thereto.

Further, a sintering agent is added to thereby control the interfacial bonding with magnetic material, whereby delamination of the bonding portion between a magnetic layer and a non-magnetic layer, affecting the yield of a ceramic electronic component, can be avoided.

While the present invention has been shown and described in connection with the exemplary embodiments, it will be apparent to those skilled in the art that modification and variation can be made without departing from the spirit and scope of the invention as defined by the appended claims.

What is claimed is:

1. A non-magnetic material composition for a ceramic electronic component comprising a compound represented by Chemical Formula Zn₂TiO₄.

2. The non-magnetic material composition of claim 1, wherein the compound is a powder.

3. The non-magnetic material composition of claim 1, wherein the compound is prepared by mixing and calcining zinc oxide (ZnO) and titanium dioxide (TiO₂).

4. The non-magnetic material composition of claim 3, wherein the compound is prepared by reacting 0.65 mol to 0.67 mol of zinc oxide and 0.33 mol to 0.35 mol of titanium dioxide.

5. The non-magnetic material composition of claim 1, further comprising a sintering agent.

6. The non-magnetic material composition of claim 5, wherein the sintering agent is at least one selected from the group consisting of B₂O₃ and CuO.

7. The non-magnetic material composition of claim 6, wherein the sintering agent is 1 to 5 parts by weight per 100 parts by weight of the compound.

8. A ceramic electronic component comprising:
a ceramic main body in which a plurality of magnetic layers are stacked;
internal electrode layers formed in the ceramic main body;
a non-magnetic layer inserted between the magnetic layers and including a compound represented by Chemical Formula Zn₂TiO₄; and
external electrodes formed on outside ends of the ceramic main body and electrically connected with the internal electrode layers.

9. The ceramic electronic component of claim 8, wherein the compound is prepared by mixing and calcining zinc oxide (ZnO) and titanium dioxide (TiO₂).

10. The ceramic electronic component of claim 9, wherein the compound is prepared by reacting 0.65 mol to 0.67 mol of zinc oxide and 0.33 mol to 0.35 mol of titanium dioxide.

11. The ceramic electronic component of claim 8, further comprising a sintering agent.

12. The ceramic electronic component of claim 11, wherein the sintering agent is at least one selected from the group consisting of B₂O₃ and CuO.

13. The ceramic electronic component of claim 12, wherein the sintering agent is 1 to 5 parts by weight per 100 parts by weight of the compound.

14. A method of manufacturing a ceramic electronic component, the method comprising:
preparing a plurality of magnetic layers;
preparing a non-magnetic layer including a compound represented by Chemical Formula Zn₂TiO₄;
forming internal electrode layers in the plurality of magnetic layers;
forming a laminate by inserting the non-magnetic layer between the plurality of magnetic layers;
forming a ceramic main body by firing the laminate; and
forming external electrodes on outside ends of the ceramic main body to be electrically connected with the internal electrode layers.

15. The method of claim 14, wherein the compound is prepared by mixing and calcining zinc oxide (ZnO) and titanium dioxide (TiO₂).

16. The method of claim 15, wherein the compound is prepared by reacting 0.65 mol to 0.67 mol of zinc oxide and 0.33 mol to 0.35 mol of titanium dioxide.

17. The method of claim 14, further comprising a sintering agent.

18. The method of claim 17, wherein the sintering agent is at least one selected from the group consisting of B₂O₃ and CuO.

19. The method of claim 18, wherein the sintering agent is 1 to 5 parts by weight per 100 parts by weight of the compound.

20. The method of claim 14, wherein the non-magnetic layer is centeredly-inserted between the magnetic layers in the laminate.

21. The method of claim 14, wherein the laminate has at least one non-magnetic layer inserted between the magnetic layers.
